(19) United States
(12) Patent Application Publication
(10) Pub. No.: US 2025/0019821 A1
(43) Pub. Date: Jan. 16, 2025

(54) COATING METHOD

(71) Applicant: SAFRAN CERAMICS, Le Haillan (FR)

(72) Inventors: Eric BOUILLON, Moissy-Cramayel (FR); Lisa PIN, Moissy-Cramayel (FR); Simon ARNAL, Moissy-Cramayel (FR); Benjamin COSSOU, Moissy-Cramayel (FR)

(73) Assignee: SAFRAN CERAMICS, Le Haillan (FR)

(21) Appl. No.: 18/713,007

(22) PCT Filed: Nov. 21, 2022
(86) PCT No.: PCT/FR2022/052143

§ 371 Date: May 23, 2024

(30) Foreign Application Priority Data
Nov. 24, 2021 (FR) FR2112447

(51) Int. Cl. C23C 16/24; C23C 16/56; F01D 5/28

(52) U.S. Cl. CPC C23C 16/24; C23C 16/56; F01D 5/286; F05D 2230/90

(57) ABSTRACT

A method including a step of forming a bond coating on a surface of a substrate, and a step of forming a barrier coating on the bond coating. The bond coating is formed by chemical vapor deposition, at a deposition temperature higher than 150° C., in particular 1200° C. or higher, of a precursor including silicon, and includes columnar grains of crystalline silicon.

### TECHNICAL FIELD

This disclosure concerns the field of coatings and more particularly to that of coating methods, especially for protecting ceramic-based substrates from aggressive environments.

### PRIOR ART

Ceramic matrix composite materials (CMC), and in particular those based on carbide (generally referred to as SiC/SiC), have been proposed for numerous applications, and especially for the production of gas turbine parts, such as blades and nozzles. Indeed, by virtue of their heat-resistant properties, these materials make it possible to reduce or even eliminate the cooling conventionally used in nickel and/or cobalt-based metal turbine parts, while allowing an increase in operating temperatures.

However, in the corrosive environment of a turbine, SiC/SiC CMCs can be subjected to oxidation resulting in the formation of silicon oxide, and volatilization of this silicon oxide under the effect of water vapor. Thus, for applications at high temperature in an environment rich in oxygen and water vapor, the application of a protective coating on ceramic matrix composite parts is recommended.

Because of the particularly aggressive thermomechanical and chemical environment to which the protective coating could be subjected, it should preferably have an expansion coefficient compatible with that of the substrate, and a low permeability to corrosive species (this includes both a low molecular diffusion directly related to the physical hermeticity parameter and a low ionic diffusion of superoxide and hydroxide ions, intrinsic characteristics of rare earth silicates) and thermomechanical stability at high temperatures, such as those prevailing in a gas turbine. For this purpose, the protective coating can typically comprise a barrier coating or environmental barrier coating (EBC), usually based on rare earth silicate and, between the substrate and the barrier coating, a bond coating, generally silicon-based, to ensure their adhesion. The oxidation of the silicon of the bond coating can also form an intermediate layer of silica, called thermal growth oxide (TGO), between the bond coating and the barrier coating.

The application of protective coatings to substrates having complex shapes, such as turbine blades, can also impose geometric constraints, particularly at thin leading or trailing edges, or cooling ducts or cavities, with very small coating thicknesses so as not to affect the aerodynamic performance of the blades or their possible cooling.

In addition, although the formation of the thermal growth oxide interlayer may help protect silicon carbide-containing substrates from corrosion, it can also have induced thermomechanical effects, such as, for example, the generation of mechanical stresses between the bond coating and the barrier coating, because of the increase in volume of silicon by oxidizing to form silica and the allotropic transformation of silica, also associated with a change in volume. Consequently, from a critical thickness of the thermal growth oxide intermediate layer, mechanical stresses can result in dome cracking, eventually leading to partial or total flaking of the barrier coating and thus to the loss of the anti-corrosion function.

For these reasons, it is therefore appropriate to restrict the thickness of the coatings, and in particular of the bond coating. Generally, the bond and barrier coatings are applied by thermal spraying. However, in order to ensure complete coverage of the substrate, this normally involves thicknesses of at least 75 μm for the bond coating and of at least 100 μm for the barrier coating, thicknesses which may be excessive for the above-mentioned reasons.

In order to offer alternatives, the publications of patent applications US Patent No. 2020/0039892 A1 and US Patent No. 2020/0039886 A1 have proposed coating methods each comprising a step of forming a bond coating on a surface of a substrate and a step of forming a barrier coating on the bond coating, wherein the bond coating comprises columnar grains of crystalline silicon and is formed by chemical vapor deposition of a precursor comprising silicon.

Although these methods make it possible to obtain finer thicknesses than thermal spraying, in particular for the bond coating, it may be appropriate to reduce the thickness of the latter even further compared with what is proposed in these publications.

### DISCLOSURE OF THE INVENTION

The present disclosure concerns a coating method, comprising a step of forming a bond coating on a surface of a substrate by chemical vapor deposition of a precursor comprising silicon, the bond coating comprising columnar grains of crystalline silicon, and a step of forming a barrier coating on the bond coating. In order to obtain a particularly fine bond coating, the step of forming the bond coating can be carried out with a deposition temperature greater than 1150° C., preferably equal to or greater than 1200° C. Moreover, the step of forming the bond coating can be carried out with a deposition pressure of less than 10 kPa, whereas the precursor for the step of forming the bond coating can comprise a relatively unreactive precursor, in particular trichlorosilane and/or silicon tetrachloride.

Due to these deposition parameters, it is possible to obtain a particular microstructure of the bond coating, with columnar grains of pure silicon with an average length of approximately 75% of the thickness of the bond coating, offering good coverage of the substrate even with a very fine thickness. Thus, the bond coating can have a maximum thickness of less than 20 μm, preferably less than 10 μm.

In order to protect the substrate from a particularly aggressive environment, the barrier coating can comprise a rare earth silicate, in particular ytterbium disilicate. In order to obtain a good coverage of the substrate with a small thickness of this barrier coating, even in cavities that are difficult to access, the barrier coating formation step can be carried out by liquid deposition, for example by dip coating and/or electrophoresis. The barrier coating can have a maximum thickness of less than 40 μm, preferably less than 30 μm.

The method can comprise an additional step of forming a protective coating against degradation by calcium-magnesium-aluminosilicates. The substrate can form a turbine part, particularly in a gas turbine engine, and/or comprise an at least partially ceramic material, particularly a ceramic matrix composite material.

### BRIEF DESCRIPTION OF THE DRAWINGS

FIG. 1 is a microphotograph in cross-section of a substrate covered with a bond coating and a barrier coating applied according to a coating method according to one embodiment.

FIG. 2 schematically represents a gas turbine engine.

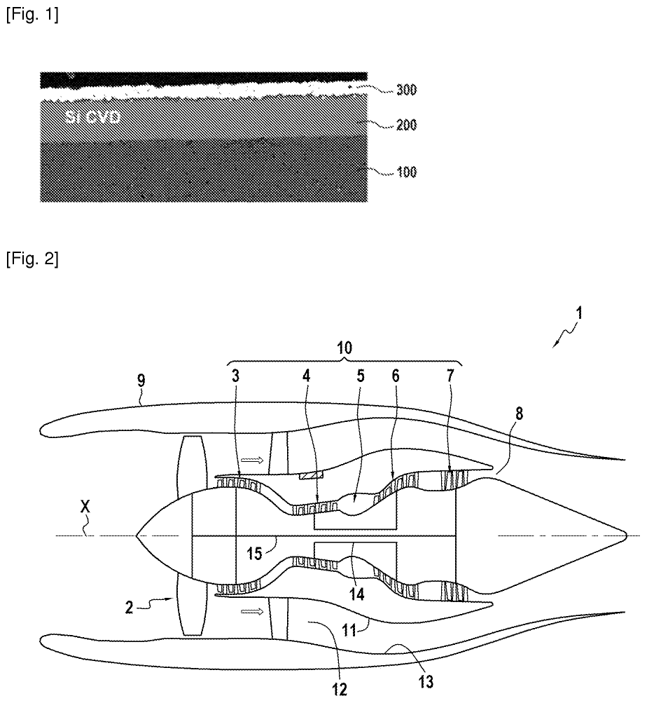

### DESCRIPTION OF THE EMBODIMENTS

The invention will be well understood and its advantages will become clearer on reading the following detailed description of an embodiment shown by way of non-limiting example.

In a first step of the method according to this embodiment, a surface of an at least partially ceramic substrate 100, which can, for example, be a ceramic matrix composite material (CMC), and especially a SiC/SiC CMC, can first be subjected to chemical vapor deposition to form a bond coating 200. In this step of forming the bond coating 200, the precursor used can comprise, for example, trichlorosilane (HCbSi) and/or silicon tetrachloride (SiCl4), and the chemical vapor deposition can be carried out at a temperature higher than 1150° C., or even equal to or greater than 1200° C. and a pressure less than, for example, 10 kPa, or even equal to or less than 1 kPa, so as to form a bond coating 200 of a thickness less than, for example, 20 μm or even less than 10 μm, and having a columnar microstructure with crystalline silicon grains with an average length of, for example, approximately 75% of the thickness of the bond coating 200. At these temperatures, the deposition rate can vary from 2 to 20 μm/h depending on the pressure and the precursor used. The duration of this step can therefore vary between 30 minutes and 10 hours for the thicknesses targeted. This step can in particular be carried out in a hot-wall reactor, in order to carry out the deposition independently of the geometry of the substrate 100.

In a second step of the method according to this embodiment, a barrier coating 300 can be formed on the bond coating 200 by a known deposition method, such as liquid deposition, for example by dipping or electrophoresis, or chemical vapor deposition. This barrier coating 300 can in particular comprise a rare earth silicate, such as, for example, ytterbium disilicate (Yb₂Si₂O₇), as well as other components, such as, for example, trivalent iron oxide (Fe₂O₃), and can have a maximum thickness of less than 40 μm, or even less than 30 μm.

In a subsequent step, it is conceivable to apply, to the barrier coating 300, an additional coating (not shown) for protection against degradation by calcium-magnesium-aluminosilicates (CMAS). This additional coating can comprise a rare earth silicate, and in particular a rare earth monosilicate such as ytterbium monosilicate (Y₂SiO₅). It can be applied by a known deposition method such as plasma spray deposition, liquid deposition or chemical vapor deposition. Its thickness can be, for example, between 5 and 100 μm.

In a final step, all the superimposed coatings can be subjected to a stabilizing heat treatment.

The coatings obtained by this method are particularly resistant to aggressive environments at high temperatures, and are particularly applicable to turbine parts exposed to combustion gases, such as, for example, blades and nozzles of gas turbine engines. FIG. 2 schematically illustrates a gas turbine engine 1, more specifically in the form of a turbofan engine, although the method is also applicable to turbine parts of other types of turbomachines and gas turbine engines, such as turbojets, turboprops, turboshafts, or even turbo-pumps and turbochargers. In the direction of fluid flow, this gas turbine engine 1 can comprise a fan 2, a low pressure compressor 3, a high pressure compressor 4, a combustion chamber 5, a high pressure turbine 6, a low pressure turbine 7 and a nozzle 8. The assembly can be surrounded by a nacelle 9. The compressors 3, 4, the combustion chamber 5 and the turbines 6, 7 together form the gas generator 10, which can itself be surrounded by a fairing 11 ending in the nozzle 8. Thus, an air stream 12 of the fan 2 can be defined between the fairing 11 of the gas generator 10 and an internal wall 13 of the nacelle 9. The high-pressure turbine 6 can be connected to the high-pressure compressor 4 by a first rotating shaft 14 for driving the latter, whereas the low pressure turbine 7 can be connected to the fan 2 and to the low pressure compressor 3 by a second rotating shaft 15 coaxial with the first rotating shaft 14, in a similar manner.

In such a gas turbine engine 1, the parts of the high pressure turbine 6 and low pressure turbine 7, especially the blades and nozzles, are subjected to considerable mechanical stresses in the particularly aggressive environment of the combustion gases. They can therefore benefit from the coating method described above.

Although the present invention has been described with reference to a specific embodiment, it is obvious that various modifications and changes can be made to these examples without exceeding the general scope of the invention as defined by the claims. Therefore, the description and drawings must be considered in an illustrative rather than restrictive sense.

1. A coating method comprising the following steps:
forming a bond coating on a surface of a substrate by chemical vapor deposition of a precursor comprising silicon, the bond coating comprising columnar grains of crystalline silicon,
forming a barrier coating on the bond coating, the method being characterized in that the bond coating has a maximum thickness of less than 20 μm, and in that the step of forming the bond coating is carried out with a deposition temperature greater than 1150° C., in particular equal to or greater than 1200° C.

2. The coating method according to claim 1, wherein the step of forming the bond coating is performed at a deposition pressure of less than 10 kPa.

3. The coating method according to claim 1, wherein the precursor for the step of forming the bond coating comprises trichlorosilane and/or silicon tetrachloride.

4. The coating method according to claim 1, wherein the step of forming the barrier coating is by liquid deposition.

5. The coating method according to claim 1, wherein the barrier coating comprises a rare earth silicate, in particular ytterbium disilicate.

6. The coating method according to claim 1, comprising an additional step of forming a protective coating against degradation by calcium magnesium aluminosilicates.

7. The coating method according to claim 1, wherein the bond coating has a maximum thickness of less than 10 μm.

8. The coating method according to claim 1, wherein the barrier coating has a maximum thickness of less than 40 μm, preferably less than 30 μm.

9. The coating method according to claim 1, wherein the substrate comprises an at least partially ceramic material, in particular a ceramic matrix composite material.

10. The coating method according to claim 1, wherein the substrate forms a turbine part.
